(19) United States
(12) Patent Application Publication
(10) Pub. No.: US 2011/0297978 A1
(43) Pub. Date: Dec. 8, 2011

(54) LIGHT-EMITTING DIODE, METHOD FOR MANUFACTURING THE SAME, AND LIGHT-EMITTING DIODE LAMP

(75) Inventors: Ryouichi Takeuchi, Chichibu-shi (JP); Noritaka Muraki, Chichibu-shi (JP)

(73) Assignee: SHOWA DENKO K.K., Minato-ku, Tokyo (JP)

(21) Appl. No.: 13/202,274

(22) PCT Filed: Jan. 21, 2010
(86) PCT No.: PCT/JP2010/000338

§ 371 Date: Aug. 18, 2011

(30) Foreign Application Priority Data
Feb. 20, 2009 (JP) 2009-038238

(51) Int. Cl. H01L 33/48; H01L 33/60

(52) U.S. Cl. 257/89; 257/98; 438/29; 257/E33.06; 257/E33.056

(57) ABSTRACT

The invention provides a high luminance light-emitting diode capable of reducing the loss of light emitted from LED chips in a package and also capable of improving the light extraction efficiency from the package, wherein

the light-emitting diode (1) includes a compound semiconductor layer (2) including a light-emitting portion (8) having a light-emitting layer (9) and a substrate (3), in which an external reflection layer (4) having a reflectivity higher than that of the substrate (3) is provided on a side surface of the substrate (3).

### TECHNICAL FIELD

The present invention relates to a light-emitting diode, a method for manufacturing the same, and a light-emitting diode lamp.

This application claims priority based on Japanese Patent Application No. 2009-038238 filed in the Japanese Patent Office on Feb. 20, 2009, and the contents of which are incorporated herein by reference.

### BACKGROUND ART

Hitherto, as a high luminance light-emitting diode (LED) that emits red, orange, yellow, or yellow-green visible light, a compound semiconductor LED has been known which is provided with a light-emitting layer composed of aluminum phosphide, gallium, and indium (with an empirical formula of (Al_{X}Ga_{1-X})_{Y}In_{1-Y}P; 0≦X≦1, 0<Y≦1). In such an LED, a light-emitting portion provided with the light-emitting layer composed of (Al_{X}Ga_{1-X})_{Y}In_{1-Y}P (0≦X≦1, 0<Y≦1) is formed on a substrate material, such as gallium arsenide (GaAs) which is, in general, optically opaque to light emitted from the light-emitting layer and is also not very strong mechanically.

Therefore, in recent years, in order to produce a visible LED with higher luminance, and for the purposes improving the mechanical strength of an element, technologies have been disclosed in which the substrate material opaque to emitted light is removed, and then a supporting layer (substrate) composed of a material that transmits or reflects emitted light and is excellent in terms of mechanical strength is joined so as to constitute a joined LED (refer to, for example, PTL 1 to 7).

Also, in package technologies using LEDs, in addition to a single color in the related art, blue, green, and red LED chips are incorporated into the same package for emitting the full range of colors so that LED products are distributed which can emit three different colors of light at the same time and thus reproduce a wide range of colors of light emission, beginning with white.

In addition, PTL 8 discloses a light-emitting element having an ohmic metal embedded in an organic adhesion layer between a metal layer and a reflection layer.

### [Citation List]

### [Patent Literature]

### [Patent Literature 1]

Japanese Patent No. 3230638

### [Patent Literature 2]

Japanese Unexamined Patent Application Publication No. 6-302857

### [Patent Literature 3]

Japanese Unexamined Patent Application Publication No. 2002-246640

### [Patent Literature 4]

Japanese Patent No. 2588849

### [Patent Literature 5]

Japanese Unexamined Patent Application Publication No. 2001-57441

### [Patent Literature 6]

Japanese Unexamined Patent Application Publication No. 2007-81010

### [Patent Literature 7]

Japanese Unexamined Patent Application Publication No. 2006-32952

### [Patent Literature 8]

Japanese Unexamined Patent Application Publication No. 2005-236303

### SUMMARY OF INVENTION

### Technical Problem

As described above, due to the development of substrate joining technologies, the degree of freedom of a substrate applicable as a supporting layer has increased such that there have been suggestions of the application of a substrate made of Si, Ge, a metal, a ceramic, GaP, or the like, which have large merits in terms of costs, mechanical strength, or the like.

However, such a substrate has a problem in that the efficiency of extracting light from a package is degraded since the substrate absorbs a large amount of light emitted from other LEDs mounted in the same package so as to induce a loss in light emission. For example, a GaP substrate is transparent to red, but absorbs a large amount of blue light. Particularly, in a full color package, since LED chips of three different colors (red, green, and blue) are adjacently disposed, for example, an AlGaInP light-emitting diode chip-mounted substrate for red light emission absorbs not only red therefrom but also light emitted from the adjacent blue and green LED chips such that there is a problem in that the overall light emission efficiency of the package is degraded.

The invention has been made in consideration of the above circumstances, and an object of the invention is to provide a high luminance light-emitting diode capable of reducing the loss of light emitted from LED chips in a package and also capable of improving the light extraction efficiency from the package, a method for manufacturing the same, and a light-emitting diode lamp.

### Solution to Problem

That is, the invention relates to the following:

(1) A light-emitting diode including a compound semiconductor layer including a light-emitting portion having a light-emitting layer and a substrate, in which an external reflection layer having a reflectivity higher than that of the substrate is provided on a side surface of the substrate.

(2) The light-emitting diode according to the above (1), in which the compound semiconductor layer and the substrate are joined, and the substrate is any of Si, Ge, a metal, a ceramic, and GaP.

(3) The light-emitting diode according to the above (1) or (2), in which the external reflection layer has a reflectivity of 90% or higher in the wavelength band of external light.

(4) The light-emitting diode according to any one of the above (1) to (3), in which the external reflection layer is constituted by a metal including at least one of silver, gold, copper, and aluminum.

(5) The light-emitting diode according to any one of the above (1) to (4), in which a stabilization layer is provided on the surface of the external reflection layer.

(6) The light-emitting diode according to any one of the above (1) to (5), in which an internal reflection layer is provided between the compound semiconductor layer and the substrate.

(7) The light-emitting diode according to any one of the above (1) to (6), in which the external reflection layer is formed by a plating method.

(8) The light-emitting diode according to any one of the above (1) to (7), in which the light-emitting layer includes an AlGaInP or AlGaAs layer.

(9) A method for manufacturing a light-emitting diode including a process in which a compound semiconductor layer including a light-emitting portion having a light-emitting layer is formed on a semiconductor substrate; a process in which the compound semiconductor layer and the substrate are joined; a process in which the semiconductor substrate is removed; and a process in which an external reflection layer is formed on a side surface of the substrate.

(10) The method for manufacturing a light-emitting diode according to the above (9), in which the process in which an external reflection layer that reflects external light is formed on a side surface of the substrate includes a plating process.

(11) A light-emitting diode lamp in which two or more light-emitting diodes are mounted, of which at least one light-emitting diode according to any one of the above (1) to (8) is mounted.

(12) The light-emitting diode lamp according to the above (11), in which the light emission wavelengths of the mounted light-emitting diodes are different.

(13) The light-emitting diode lamp according to the above (11) or (12), in which chip heights of the mounted light-emitting diodes are different.

### Effects of Invention

In the light-emitting diode of the invention, an external reflection layer having a reflectivity higher than that of a substrate is provided on a side surface of the substrate. Since the external reflection layer, for example, reflects external light such as light emitted from adjacent LED chips in a package, it is possible to reduce the loss of light emitted from the LED chips in the package. Therefore, it is possible to provide a high luminance light-emitting diode capable of improving the efficiency of extracting light from the package.

The method for manufacturing a light-emitting diode of the invention has a process in which an external reflection layer having a reflectivity higher than that of a substrate is provided on a side surface of the substrate. Therefore, it is possible to reliably manufacture the above light-emitting diode.

According to the light-emitting diode lamp of the invention, the light-emitting diode lamp mounts two or more light-emitting diodes, and mounts at least one of the above light-emitting diode. Since the external reflection layer provided in the above light-emitting diode reflects light emitted from adjacent LED chips in a package, it is possible to reduce the loss of light emitted from the LED chips in the package. Therefore, it is possible to provide a light-emitting diode lamp capable of improving the efficiency of extracting light from the package.

### BRIEF DESCRIPTION OF DRAWINGS

FIG. 1 is a view showing a light-emitting diode that is an embodiment of the invention, in which (a) is a top view and (b) is a cross-sectional view taken along the line A-A′ shown in (a).

FIG. 2 is an enlarged cross-sectional view for explaining the joined portion of a light-emitting diode that is an embodiment of the invention.

FIG. 3 is a schematic cross-sectional view of an epiwafer used in a light-emitting diode that is an embodiment of the invention.

FIG. 4 is a schematic cross-sectional view of a joined wafer used in a light-emitting diode that is an embodiment of the invention.

FIG. 5 is a view showing a light-emitting diode lamp that is an embodiment of the invention, in which (a) is a top view and (b) is a cross-sectional view taken along the line B-B′ shown in (a).

FIG. 6 is a view for explaining a light-emitting diode lamp of an embodiment of the invention, in which (a) is a top view and (b) is a cross-sectional view taken along the line C-C′ shown in (a).

### DESCRIPTION OF EMBODIMENTS

Hereinafter, a light-emitting diode and a light-emitting diode lamp, which are embodiments applying the invention, will be described in detail with reference to the accompanying drawings. Meanwhile, in the drawings used for the following description, there are cases in which characterizing portions are enlarged for convenience in order to make features easily understood, and the scale or the like of each constituent element does not necessarily match the actual one.

<Light-Emitting Diode>

It is possible to apply the invention to a light-emitting diode that is epitaxially grown on a substrate and is manufactured using an ordinary method. However, furthermore, it is more desirable to adapt the invention to a light-emitting diode using a joined substrate for which there are more choices of substrates. For example, in the case of a GaAs substrate, when As is dissolved in a plating solution, a treatment for As is required for disposal of the solution. In addition, depending on the type of plating solution, there are cases in which As shortens the service life of the plating solution. On the other hand, a sapphire substrate has an inactive surface and thus is not easily plated. A joined substrate that can be easily plated is desirable. Particularly, a metal substrate is a favorable material that can be easily plated.

Firstly, the configuration of a light-emitting diode, which is an embodiment to which the invention is applied, will be described.

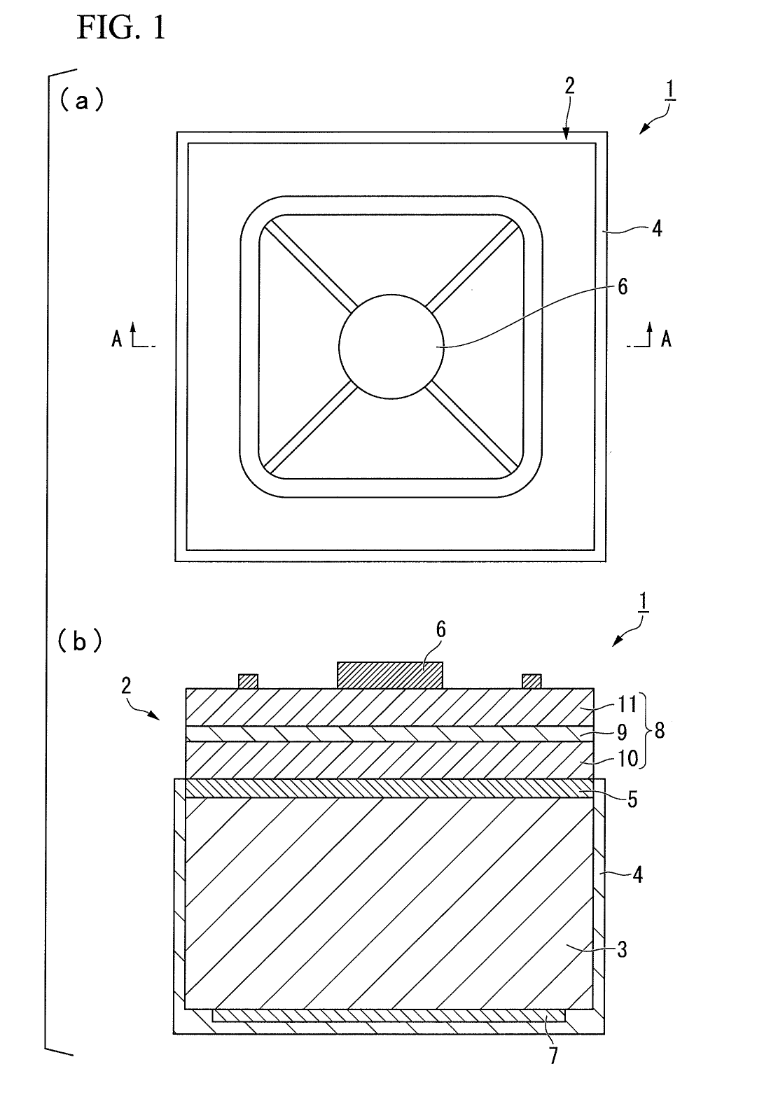

As shown in FIGS. 1(a) and 1(b), a light-emitting diode (LED) 1 of the present embodiment has a compound semiconductor layer 2 and a substrate 3 joined with each other and has an external reflection layer 4 having a reflectivity higher than that of the substrate 3 on a side surface of the substrate 3. Specifically, in the light-emitting diode 1, the compound semiconductor layer 2 and the substrate 3 are joined via a metallic connection layer 5. In addition, a first electrode 6 is provided on the top surface of the compound semiconductor layer 2, and a second electrode 7 is provided on the bottom surface of the substrate 3.

The compound semiconductor layer 2 is not particularly limited as long as it includes a pn junction-type light-emitting portion 8. The light-emitting portion 8 is a laminate structure of a compound semiconductor including a light-emitting layer 9 composed of, for example, (Al_{X}Ga_{1-X})_{Y}In_{1-X}P (0≦X≦1, 0<Y≦1), which is a source of red light. In addition, as the light-emitting layer 9 for red and infrared light emission, Al_{X}Ga_{(1-X})As can be used. The light-emitting portion 8 can be used as a red light source in a full color package and can be used in the same package together with blue and green light sources using an InGaN-based light-emitting portion. In addition, specifically, as shown in FIG. 1(b), the light-emitting portion 8 is configured by sequentially laminating, for example, a lower cladding layer 10, the light-emitting layer 9, and an upper cladding layer 11.

The light-emitting layer 9 can also be constituted by undoped, n-type or p-type conductive (Al_{X}Ga_{1-X})_{Y}In_{1-Y}P (0≦X≦1, 0<Y≦1). The light-emitting layer 9 may have any of a double hetero structure, a single quantum well (SQW) structure, or a multi quantum well (MQW) structure, but the MQW structure is preferred in order to produce light emission excellent in terms of monochromaticity. In addition, the composition of (Al_{X}Ga_{1-X})_{Y}In_{1-Y}P (0≦X≦1, 0<Y≦1) that constitutes a barrier layer and a well layer which build a quantum well (QW) structure can be determined so that a quantum level that leads to a desired light emission wavelength is formed in the well layer.

From the standpoint of producing high strength light emission, the light-emitting portion 8 preferably has a double hetero (DH) structure including the light-emitting layer 9, the lower cladding layer 10 and the upper cladding layer 11, where the lower cladding layer 10 and the upper cladding layer 11 are disposed face to face on the top and bottom sides of the light-emitting layer 9 in order to “confine” carriers that induce radiative recombination and light emission to the light-emitting layer 9. The lower cladding layer 10 and the upper cladding layer 11 are preferably made of a semiconductor material having a wider forbidden band than (Al_{X}Ga_{1-X})_{Y}In_{1-Y}P (0≦X≦1, 0<Y≦1) that constitutes the light-emitting layer 9.

In addition, intermediate layers may be formed between the light-emitting layer 9 and the lower cladding layer 10, and between the light-emitting layer 9 and the upper cladding layer 11, in order to moderately vary the discontinuity of a band between both layers. In this case, the intermediate layer is desirably made of a semiconductor material having forbidden bandwidths intermediate between the light-emitting layer 9 and the lower cladding layer 10, and between the light-emitting layer 9 and the upper cladding layer 11.

In addition, on the upper side of the light-emitting portion 8, a well-known layer structure, such as a contact layer for reducing the contact resistance of an ohmic electrode, an electric current diffusion layer for diffusing element-driving electric current in a planar manner throughout the light-emitting portion, an electric current inhibition layer or an electric current narrowing layer for, conversely, limiting areas where element-driving electric current flows, or the like, may be provided. Furthermore, the polarity of the light-emitting portion 8 on the top surface (and the bottom surface) may be p-type or n-type.

As shown in FIG. 1(b), the substrate 3 is provided for the purpose of an improvement in the mechanical strength of the light-emitting diode 1, or the like. The material of the substrate 3 is not particularly limited and may be appropriately selected according to the purpose. As the material of the substrate 3, for example, Si, Ge, a GaP semiconductor, a metal, AlN, ceramics such as alumina, or the like may be used. Specifically, for example, when Si or Ge is used as a material of the substrate 3, there is an advantage in that, particularly, increases in aperture, workability, and mechanical strength can be achieved. In addition, when, for example, a substrate based on a copper alloy, which is a metal, is used as the substrate 3, there are advantages in that costs are low, and thermal conduction is excellent. In addition, a metal substrate, AlN, and SiC, both of which have great thermal conduction, are preferred substrate materials in the formation of the external reflection layer 4, which is to be described below, from the standpoint that they can be easily adapted to a plating process.

The thickness of the substrate 3 is not particularly limited, but is preferably thin from the standpoint of light extraction efficiency, ease of working, or the like. However, it is preferable to appropriately optimize the thickness according to a material in order to prevent a decrease in yield caused by cracks, chips, and warpage during handling.

As shown in FIG. 1(b), the external reflection layer 4 covers the side surfaces and the bottom surface of the substrate 3, the side surfaces of the metallic connection layer connected to the top surface of the substrate 3, and the side surfaces of the second electrode 7 provided on the bottom surface of the substrate 3. The external reflection layer 4 is provided at the outer circumference (external portion) of the light-emitting diode 1 in order to mainly reflect external light. Meanwhile, as described below, the external reflection layer 4 is preferably formed by a plating method.

The material of the external reflection layer 4 is not particularly limited, and materials having a reflectivity of 90% or higher in the wavelength band of external light can be used. Among the materials, it is particularly preferable to use silver, aluminum, or an alloy thereof, which has a reflectivity of 90% across the entire visible light range.

On the other hand, examples of a material having a reflectivity of 90% or higher in a part of the wavelength band in the visible light range include gold and copper. Herein, gold has an increased reflectivity at a wavelength longer than about 550 nm and has a reflectivity exceeding 90% at about 590 nm. In addition, copper has an increased reflectivity at a wavelength longer than about 600 nm and has a reflectivity exceeding 90% at about 610 nm. As such, the material of the external reflection layer 4 can be appropriately selected according to the wavelength band of external light.

Meanwhile, in a light-emitting diode in the related art, there was a problem in that a large amount of light is absorbed when a substrate of GaAs, Si, and Ge is used as a base material. In addition, for example, when a copper alloy-based substrate is used as a base material, the reflectivity is high with respect to red light emission, but there was a problem in that light absorption was large with respect to blue and green light emission. In contrast to the above, in the light-emitting diode 1 of the embodiment, even when a Si or Ge substrate or a copper alloy-based substrate is used as the substrate 3, the material of the external reflection layer 4 can be appropriately selected according to the wavelength range of external light, and therefore it is possible to reduce absorption of external light at the side surfaces of the substrate 3.

In addition, depending on the material of the external reflection layer 4, it is preferable to provide a stabilization layer (not shown) in order to stabilize the surfaces of the external reflection layer 4. As the stabilization layer, for example, the surfaces of the external reflection layer 4 may be treated, or a protection layer may be formed. More specifically, when silver is used as the external reflection layer 4, silver turns into silver sulfide when exposed to air so as to blacken. Therefore, it is possible to form a stabilization layer by treating the surfaces of the external reflection layer 4 with an oxidation inhibitor.

In addition, as the material of the external reflection layer 4, a nonmetal can also be applied. Specifically, for example, white alumina, AlN, a resin, a mixture thereof, or the like can be appropriately selected according to the wavelength range of light emitted. Meanwhile, when a nonmetal was selected as a material of the external reflection layer 4, there are cases in which efforts are required for the formation of the external reflection layer 4.

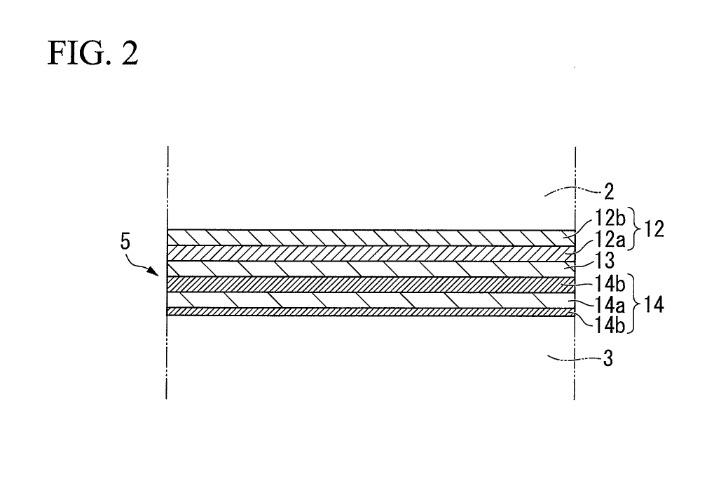

As shown in FIG. 1(b), the metallic connection layer 5 is provided between the compound semiconductor layer 2 and the substrate 3 and has a laminate structure capable of increased luminance, conduction properties, and stabilization of a mounting process. Specifically, as shown in FIG. 2, the metallic connection layer 5 is roughly configured in which at least an internal reflection layer 12, a barrier layer 13, and a connection layer 14 are laminated from the bottom surface of the compound semiconductor layer 2.

The internal reflection layer 12 is provided, for the purpose of an increase in the luminance of the light-emitting diode 1, in order to mainly reflect light emitted from the light-emitting portion 8 to the substrate 3 so as to efficiently extract the light outward. As shown in FIG. 2, the internal reflection layer 12 preferably has a reflection structure with a high reflectivity constituted by a reflection film 12a and a transparent conductive film 12b.

As the reflection film 12a, a metal having a high reflectivity can be applied. Specifically, examples of the metal include silver, gold, aluminum, platinum, and an alloy of these metals.

The transparent conductive film 12b is provided between the substrate 3 and the reflection film 12a. The transparent conductive film 12b can prevent diffusion and a reaction between a metal constituting the reflection film 12a and a semiconductor substrate constituting the substrate 3 when the substrate 3 is a semiconductor substrate. Thereby, a decrease in the reflectivity of the internal reflection layer 12 can be suppressed. In addition, as the transparent conductive layer 12b, it is preferable to use, for example, indium tin oxide (ITO), indium zinc oxide (IZO), or the like.

As shown in FIG. 2, the barrier layer 13 is provided between the internal reflection layer 12 and the connection layer 14. The barrier layer 14 has a function of suppressing the mutual diffusion between a metal constituting the internal reflection layer 12 and a metal constituting the connection layer 14 so as to prevent a decrease in the reflectivity of the internal reflection layer 12. As the barrier layer 14, for example, a well-known high melting point metal, such as tungsten, molybdenum, titanium, platinum, chromium, tantalum, or the like, can be applied.

As shown in FIG. 2, the connection layer 14 is provided on the side facing the substrate 3. The connection layer 14 is preferably constituted by a material that has a low electric resistance and can be connected at a low temperature, that is, a layer (a low melting point metal layer) 14a made of a low melting point metal. As the low melting point metal layer 14a, an In or Sn metal and a well-known soldering material can be applied, but it is preferable to use an Au-based eutectic metal material that is chemically stable and has a low melting point.

Examples of the Au-based eutectic metal material include AuSn, AuGe, AuSi, or the like. In addition, when an Au-based eutectic metal material is used as the low melting point metal layer 14a, it is preferable to form Au layers 14b on and beneath the low melting point metal layer 14a. By forming the Au layers 14b in the above manner, the composition is varied after melting so as to increase the melting point, and therefore heat resistance can be improved during the mounting process.

The first electrode 6 is a low resistance ohmic contact electrode provided on the top surface of the compound semiconductor layer 2. On the other hand, the second electrode 7 is a low resistance ohmic contact electrode provided on the bottom surface of the substrate 3. In the embodiment, the polarities of the first electrode 6 and the second electrode 7 are n-type and p-type respectively, or the polarities of the first electrode 6 and the second electrode 7 are p-type and n-type respectively.

For example, when the first electrode 6 is an n-type ohmic electrode, it is possible to form the electrode using, for example, AuGe, AuSi, or the like. On the other hand, when the second electrode is, for example, a p-type ohmic electrode, it is possible to form the electrode using, for example, AuBe, AuZn, or the like. In addition, as the surface material of the first electrode 6 and the second electrode 7, gold is generally used in order to cope with mounting by wire bonding. Meanwhile, in order to uniformly diffuse electric current to the light-emitting portion 8, it is preferable to conform the shape or disposition of the first electrode 6 to the light-emitting portion 8. The shape and disposition of the first electrode 6 are not particularly limited, and well-known technologies may be applied.

<Method for Manufacturing Light-Emitting Diode>

Next, a method for manufacturing the light-emitting diode 1 of the embodiment will be described. At least, the method for manufacturing the light-emitting diode 1 of the embodiment includes a process in which a compound semiconductor layer including a light-emitting portion having a light-emitting layer is formed on a semiconductor substrate, and a process in which an external reflection layer is formed on the side surfaces of the substrate. Furthermore, in the case of a light-emitting diode in which a high luminance substrate is joined, a process in which the compound semiconductor layer and the substrate are joined and a process in which the semiconductor substrate is removed are added.

(Process for Forming Compound Semiconductor Layer)

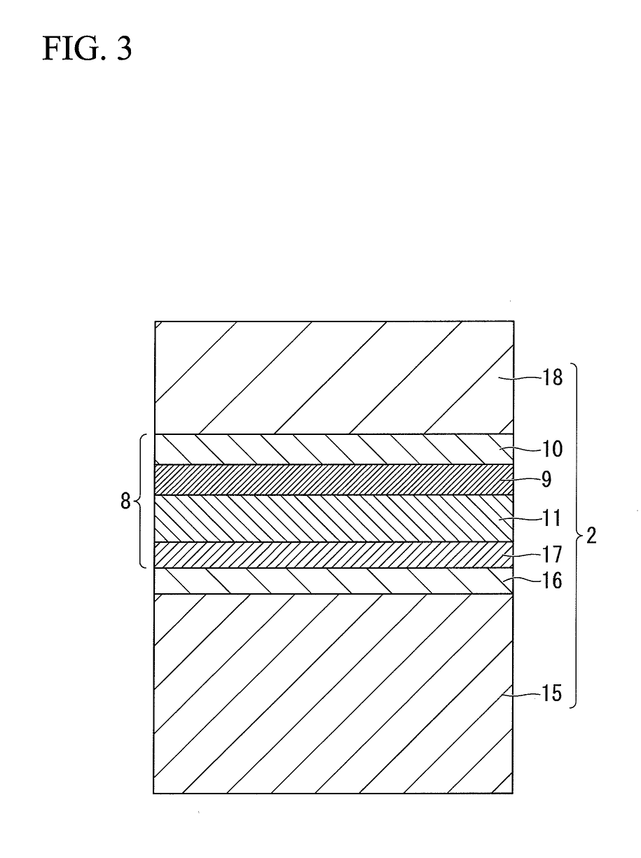

Firstly, as shown in FIG. 3, the compound semiconductor layer 2 is manufactured. The compound semiconductor layer 2 is manufactured by sequentially laminating a buffer layer 16 made of Si-doped n-type GaAs, an etching stop layer (not shown), a contact layer 17 made of Si-doped n-type AlGaInP, an n-type upper cladding layer 11, the light-emitting layer 9, a p-type lower cladding layer 10, and a Mg-doped p-type GaP layer 18 on the semiconductor substrate 15 made of, for example, a GaAs single crystal or the like. Herein, the buffer layer 16 is provided to alleviate lattice mismatch between the semiconductor substrate 15 and the constituent layers of the light-emitting portion 8. In addition, the etching stop layer is provided to be used for selective etching.

Specifically, each of the layers constituting the above compound semiconductor layer 2 can be epitaxially grown and thus laminated on the GaAs substrate 15 using a reduced-pressure metal organic chemical vapor deposition (MOCVD) method in which, for example, trimethylaluminum ((CH₃)₃Al ), trimethylgallium ((CH₃)₃Ga), and trimethylindium ((CH₃)₃In) are used as raw materials of the constituent elements belonging to Group III. As a raw material for doping Mg, for example, biscyclopentadienyl magnesium (bis-(C₅H₅)₂Mg) or the like can be used. In addition, for example, disilane (Si₂H₆) or the like can be used as a raw material for doping Si. In addition, phosphine (PH₃), arsine (AsH₃), or the like can be used as a raw material of the constituent elements belonging to Group V. In addition, with regard to a temperature at which each of the layers is grown, the p-type GaP layer 18 can be set at 750° C., and the other layers can be set at 730° C. Furthermore, the carrier concentration and thickness of each of the layers can be appropriately selected.

(Process for Joining Substrate)

Next, the compound semiconductor layer 2 and the substrate 3 are joined. For joining the compound semiconductor layer 2 and the substrate 3, firstly, the surface of the p-type GaP layer 18 constituting the compound semiconductor layer 2 is polished to a mirror-like finishing.

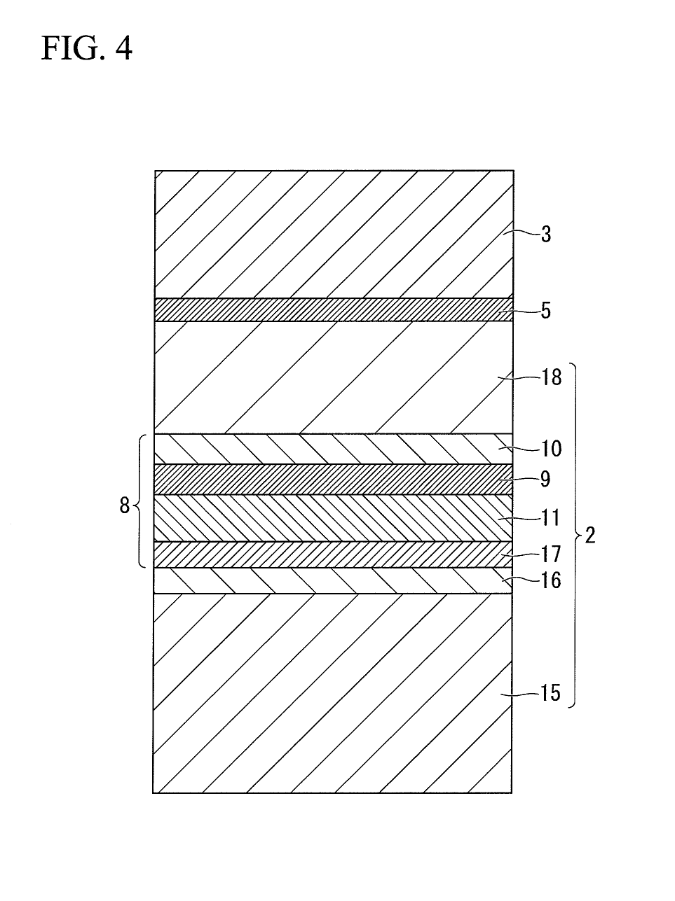

Next, as shown in FIG. 4, an ohmic electrode is formed on the mirror-like finished surface of the p-type GaP layer 18. Specifically, for example, AuBe/Au is laminated using a vacuum vapor deposition method so as to have an arbitrary thickness. After that, patterning is performed using an ordinary photolithography means so as to form a desired shape. Next, the metallic connection layer 5 is formed. Specifically, the metallic connection layer 5 is formed in the following manner: for example, a 0.1 μm-thick ITO film, which is the transparent conductive film 12b, is formed on the mirror-like finished surface of the p-type GaP layer 18 by a sputtering method, and then a 0.1 μm-thick silver alloy film, which is the reflection film 12a, is formed so as to form the internal reflection layer 12. Next, for example, a 0.1 μm-thick tungsten film is formed on the internal reflection layer 12 as the barrier layer 13. Next, a 0.5 μm-thick Au layer 14b, a 1 μm-thick AuSn (eutectic: melting point of 283° C.) film, which is the low melting point metal layer 14a, and a 0.1 μm-thick Au film are formed sequentially on the barrier layer 13 so as to form the connection layer 14.

Next, the substrate 3 attached to the mirror-like polished surface of the p-type GaP layer 18 is prepared. As the substrate 3, for example, a Ge substrate having the same thermal expansion coefficient as the light-emitting portion 8 is used. On the surface of the substrate 3, for example, a 0.1 μm-thick platinum film and a 0.5 μm-thick gold film are formed. Next, the compound semiconductor layer 2 and the substrate 3 are transported into an ordinary semiconductor material attaching apparatus, and the apparatus is evacuated to a vacuum. After that, in the attaching apparatus maintained in the vacuum state, the surfaces of the compound semiconductor layer 2 and the substrate 3 can be overlapped, heated, and subjected to a load, thereby being joined (see, FIG. 4).

Meanwhile, the method for connecting the compound semiconductor layer 2 and the substrate 3 is not limited to the above method using the metallic connection layer 5, and a well-known method, such as a diffused junction, an adhesive, a room temperature joining method, or the like, can be used, and it is possible to appropriately select a structure that is suitable for the joining method.

(Process for Removing Semiconductor Substrate)

Next, the semiconductor substrate 15 composed of GaAs and the buffer layer 16 are selectively removed from the compound semiconductor layer 2 joined to the substrate 3 using an ammonia-based etchant.

(Process for Forming First and Second Electrodes)

Next, the first electrode 6 is formed. The formation of the first electrode 6 forms an n-type ohmic electrode on the surface of the exposed contact layer 17. Specifically, for example, after AuGe and Ni alloy/Pt/Au are laminated using a vacuum vapor deposition method so as to have an arbitrary thickness, patterning is performed using an ordinary photolithography means, thereby forming the first electrode 6 into an arbitrary shape.

Next, the second electrode 7 is formed. The formation of the second electrode 7 forms an ohmic electrode on the bottom surface of the substrate 3. Specifically, for example, a 0.1 μm-thick platinum film and a 0.5 μm-thick gold film are formed. After that, a thermal treatment is performed under the conditions of, for example, 450° C. for 3 minutes so as to alloy both metals so that low resistance n-type and p-type ohmic electrodes can be formed respectively.

(Cutting Process)

Next, the light-emitting diode 1 is cut into a chip. Specifically, firstly, before cutting the light-emitting diode 1 into chips, the light-emitting portion 8 in the cutting region is removed by etching. Next, a protective film of silicon oxide or the like is formed on the light-emitting portion 8. The protective film is preferably provided to ease handling in the subsequent processes. After that, the substrate and the connection layer are cut by a laser with a 0.7 mm-pitch.

(Process for Forming External Reflection Layer)

Next, the external reflection layer 4 is formed on the side surfaces of the substrate 3. The method for forming the external reflection layer 4 is not particularly limited, and a well-known printing method, a coating method, and a plating method can be used, but a plating method capable of forming a metallic film uniformly and conveniently is particularly preferred. When a plating method is used to form the external reflection layer 4, specifically, firstly, the surface of the light-emitting portion 8 is protected with a pressure-sensitive adhesive sheet or the like which is tolerant to a plating solution, and then, for example, silver plating is performed. Thereby, the external reflection layer 4 made of silver, which is a reflective material, can be formed on the side surfaces and the bottom surface of the substrate 3. Meanwhile, the reflection film made of silver has a reflectivity of 95% or higher with respect to visible light (blue, green, and red).

In the above manner, the light-emitting diode 1 of the embodiment can be manufactured.

<Light-Emitting Diode Lamp>

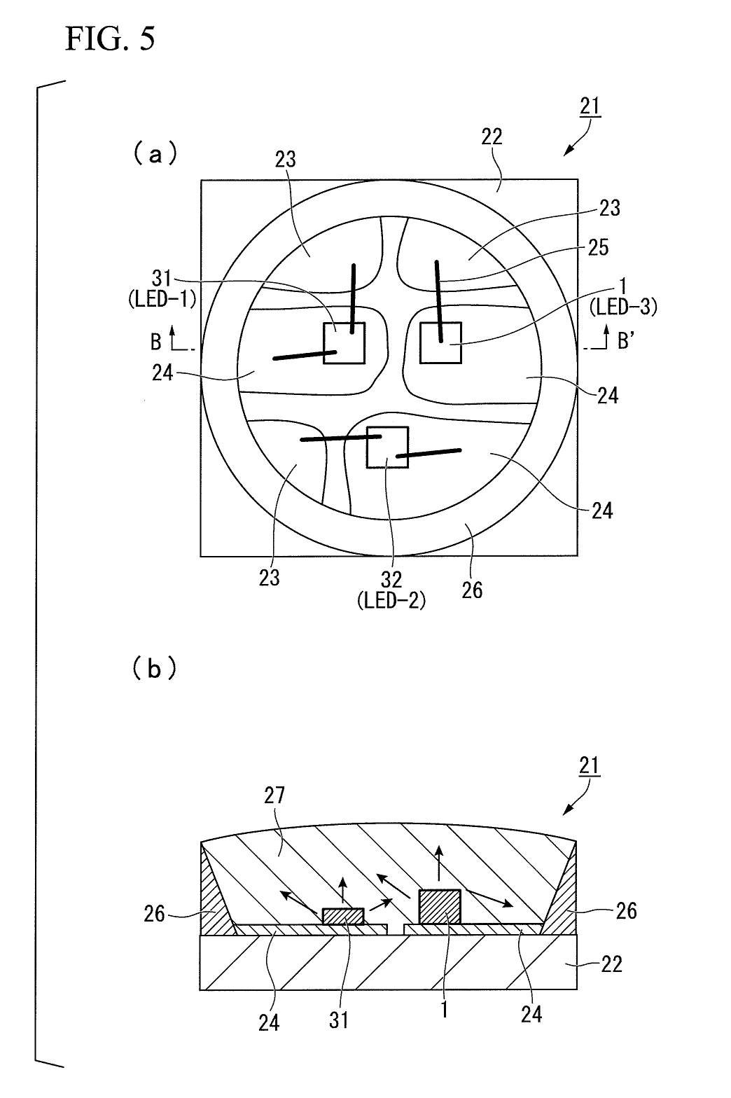

Next, the configuration of a light-emitting diode lamp, which is an embodiment to which the invention is applied, will be described. As shown in FIGS. 5(a) and 5(b), the light-emitting diode lamp 21 of the embodiment is roughly configured in which three light-emitting diodes 1, 31, and 32 are mounted on the surface of a mounting substrate 22. More specifically, the light-emitting diode 1 is a red light-emitting diode having an AlGaInP light-emitting layer 8 using a GaAs substrate as described above, and the light-emitting diodes 31 and 32 are blue and green light-emitting diodes having a GaInN light-emitting layer using a sapphire substrate. In addition, while the chip height of the light-emitting diode 1 is about 180 μm, those of the light-emitting diodes 31 and 32 are about 80 μm.

In addition, a plurality of n electrode terminals 23 and p electrode terminals 24 are provided on the surface of the mounting substrate 22, and the light-emitting diode 1 is fixed and supported (mounted) on the p electrode terminals 24 on the mounting substrate 22 with a silver (Ag) paste. In addition, the first electrode 6 in the light-emitting diode 1 and the n electrode terminals 23 on the mounting substrate 22 are connected using a gold wire 25 (wire bonding). Similarly, the light-emitting diodes 31 and 32 are fixed and supported (mounted) on the p electrode terminals 24 with a silver (Ag) paste, and the first and second electrodes (not shown) are connected to the n electrode terminals 23 and the p electrode terminals 24, respectively, using the gold wire 25. Additionally, on the surface of the mounting substrate 22, a reflection wall 26 is provided so as to cover the surrounding of the light-emitting diodes 1, 31, and 32, and the space inside the reflection wall 26 is sealed with a common sealing material 27, such as an epoxy resin or the like. In the above manner, the light-emitting diode lamp 21 of the embodiment has a configuration in which red, blue, and green light-emitting diodes are incorporated into the same package (3 in 1 package).

A case in which the red light-emitting diode 1, and the blue and green light-emitting diodes 31 and 32 are made to emit light at the same time in the light-emitting diode lamp 21 having the above configuration will be described (a case of internal light emission and reflection of external light).

As shown in FIG. 5(b), upward light emitted from the light-emitting portion in each of the light-emitting diodes 1, 31, and 32 is light emitted from the main light extraction surface. Therefore, direct extraction toward the outside of the light-emitting diode lamp 21 is possible. In addition, downward light emitted from the light-emitting portion in each of the light-emitting diodes 1, 31, and 32 cannot be directly extracted toward the outside of the light-emitting diode lamp 21.

Herein, the light-emitting diode 1 is provided with the internal reflection layer 12 constituting the metallic joining layer 5 between the compound semiconductor layer 2 and the substrate 3. Therefore, internal light by the light-emitting diode 1 is reflected by the internal reflection layer 12, and therefore it is possible to efficiently extract light emitted from the light-emitting portion 8 toward the outside of the light-emitting diode lamp 21 with no absorption of light emitted from the light-emitting portion 8 by the substrate 3. Therefore, it is possible to provide the high luminance light-emitting diode 1 and the light-emitting diode lamp 21.

In addition, light emitted from the light-emitting portion in each of the light-emitting diodes 1, 31, and 32 in the circumferential direction cannot be directly extracted toward the outside of the light-emitting diode lamp 21. Herein, the light-emitting diode lamp 21 is provided with the reflection wall 26 on the surface of the mounting substrate 22. Therefore, light emitted from each of the light-emitting diodes in the circumferential direction can be reflected upward by the reflection wall 26. As a result, it is possible to improve the light extraction efficiency of the light-emitting diode lamp 21.

Meanwhile, in a light-emitting diode in the related art, no external reflection layer was provided on the side surfaces of a substrate connected with a compound semiconductor layer. Therefore, light emitted from the light-emitting portion in each of light-emitting diodes in the circumferential direction was reflected by the reflection wall 26 provided on the mounting substrate 22 and also was sometimes absorbed, instead of being reflected, by the side surfaces of the substrate when being irradiated on the side surfaces of the substrate in the adjacent light-emitting diodes. As a result, there was a problem in that the overall light emission efficiency of the package was degraded.

In contrast to the above, the light-emitting diode lamp 21 of the embodiment has two or more light-emitting diodes mounted and has a configuration in which at least one or more light-emitting diodes 1 provided with the external reflection layer 4 are mounted on the side surfaces of the substrate 3 connected with the compound semiconductor layer 2. Therefore, light emitted from the adjacent light-emitting diodes 31 and 32 in the circumferential direction is reflected by the external reflection layer 4 without being absorbed even when being irradiated on the side surfaces of the substrate 3 in the light-emitting diode 1. As such, since the light-emitting diode 1 provided with the external reflection layer 4 having a higher reflectivity than the substrate 3 is included in a package, it is possible to reduce the loss of light emitted from LED chips in the package. As a result, it is possible to provide a high luminance light-emitting diode lamp 21 capable of improving the efficiency of extracting light from the package.

In the light-emitting diode lamp 21 of the embodiment, the light emission wavelengths of the mounted light-emitting diodes are different, but all of the light emission wavelengths of the mounted light-emitting diodes may be equal. In addition, in the light-emitting diode lamp 21 of the embodiment, the chip heights of the mounted light-emitting diodes are different, but all of the chip heights of the mounted light-emitting diodes may be equal.

### EXAMPLES

Hereinafter, the effects of the invention will be specifically described with reference to examples. Meanwhile, the invention is not limited to the examples.

<Comparison Test 1>

In the present comparison test, examples in which the light-emitting diode and the light-emitting diode lamp according to the present invention are manufactured will be specifically described. In addition, the light-emitting diode manufactured in the example is a red light-emitting diode having an AlGaInP light-emitting portion. Meanwhile, in the example, a red light-emitting diode is manufactured, which is more convenient than a light-emitting diode where a substrate is joined, and is composed of an epitaxial laminate structure (compound semiconductor layer) provided on a GaAs substrate. Furthermore, using a light-emitting diode lamp including the light-emitting diode as an example, the effects of the invention will be specifically described.

(Manufacture of Light-Emitting Diode)

Light-emitting diodes of Example 1 and Comparative Example 1 were manufactured, firstly, using epitaxial wafers including sequentially laminated semiconductor layers on semiconductor substrates made of Si-doped n-type GaAs single crystal having a surface inclined at 15 degrees from the (100) plane. The laminated semiconductor layers refer to a buffer layer made of Si-doped n-type GaAs, a layer (which becomes a contact layer in an example in which a substrate is joined) made of Si-doped n-type (Al_{0.5}Ga_{0.5})_{0.5}In_{0.5}P, an upper cladding layer made of Si-doped n-type (Al_{0.7}Ga_{0.3})_{0.5}In_{0.5}P, a light-emitting layer made of 20 pairs of undoped (Al_{0.2}Ga_{0.8})_{0.5}In_{0.5}P/(Al_{0.7}Ga_{0.3})_{0.5}In_{0.5}P, a lower cladding layer made of Mg-doped p-type (Al_{0.7}Ga_{0.3})_{0.5}In_{0.5}P, an intermediate layer made of thin films (Al_{0.5}Ga_{0.5})_{0.5}In_{0.5}P, and a Mg-doped p-type GaP layer.

Each of the above semiconductor layers was laminated on a GaAs substrate using a reduced-pressure organic metal chemical vapor deposition (MOCVD) method in which trimethylaluminum ((CH₃)₃Al), trimethylgallium ((CH₃)₃Ga), and trimethylindium ((CH₃)₃In) are used as the raw materials of constituent elements belonging to Group III so as to form the epitaxial wafers. As a raw material for doping Mg, biscyclopentadienyl magnesium (bis-(C₅H₅)₂Mg) was used. Disilane (Si₂H₆) was used as a raw material for doping Si. In addition, phosphine (PH₃) or arsine (AsH₃) was used as the raw material of constituent elements belonging to Group V. The GaP layer was grown at 750° C., and the other semiconductor layers were grown at 730° C.

The GaAs buffer layer had a carrier concentration of about 2×10¹⁸ cm⁻³ and a thickness of about 0.2 μm. The layer made of (Al_{0.5}Ga_{0.5})_{0.5}In_{0.5}P had a carrier concentration of about 2×10¹⁸ cm⁻³ and a thickness of about 1.5 μm. The upper cladding layer had a carrier concentration of about 8×10¹⁷ cm⁻³ and a thickness of about 1 μm. The light-emitting layer was a 0.8 μm-thick undoped layer. The lower cladding layer had a carrier concentration of about 2×10¹⁷ cm⁻³ and a thickness of 1 μm. The p-type GaP layer had a carrier concentration of about 3×10¹⁸ cm⁻³ and a thickness of 3 μm.

Next, as a second electrode, 0.15 μm-thick AuGe (with a content by mass of Ge of 12%) alloy, a 0.05 μm-thick Ni alloy, and 1 μm-thick Au were formed on the bottom surface of the substrate using a vacuum vapor deposition method so as to form an n-type ohmic electrode. After that, patterning was performed using an ordinary photolithography means, thereby forming the shape of the n-type ohmic electrode.

Next, as a first electrode, a p-type ohmic electrode was formed on the GaP surface using a vacuum vapor deposition method so that AuBe became 0.2 μm and Au became 1 μm. After that, a thermal treatment was performed at 450° C. for 3 minutes to alloy AuBe and Au so as to form low resistance p-type and n-type ohmic electrodes.

Next, before being cut into chips, the light-emitting portion in the cutting region was removed by etching. Furthermore, a silicon oxide protective film was formed on the cutting areas and the light-emitting portion not occupied by the electrodes. After that, the substrate was cut with a 0.3 mm pitch using a dicing saw. After that, the surfaces of the light-emitting portion was protected with a pressure-sensitive adhesive sheet and etched, and then a 0.5 μm-thick Ni plating layer was formed. After that, a 0.2 μm-thick silver plating layer was formed so as to form the external reflection layer on the side surfaces and the rear surface of the substrate. In the above manner, a red light-emitting diode chip with a chip height of 250 μm used for Example 1 (hereinafter referred to as an ‘LED chip’) was manufactured. Meanwhile, the Ag reflection layer had a reflectivity of 95% or higher with respect to visible light (blue, green, and red).

In contrast to the above, in the red LED chips used for Comparative Example 1, no external reflection layer was formed on the side surfaces and the rear surface of a substrate.

(Manufacture of Light-Emitting Diode Lamp)

Using the red LED chips used for Example 1 and Comparative Example 1, which had been manufactured in the above manner, full color LED lamps (light-emitting diode lamps) as shown in FIG. 5 were assembled, respectively (LED lamps of Example 1 and Comparative Example 1). Meanwhile, in all of the LED lamps, blue and green LED chips included a GaInN light-emitting layer using a sapphire substrate and had a chip height of about 80 μm. In addition, the blue and green LED chips were not provided with the external reflection layer of the invention.

(Evaluation Results of Light Emission Characteristics)

With regard to the LED lamps of Example 1 and Comparative Example 1, blue LED, green LED, and red LED were made to emit light one by one, and the light emission characteristics of each color were evaluated. Table 1 shows the evaluation results of the light emission characteristics.

TABLE 1

| | Item | LED-1 | LED-2 | LED-3 |
|---|---|---|---|---|
| | (IF = 20 mA) | Blue | Green | Red |
| Example 1 | Luminosity (mcd) | 90 | 301 | 40 |
| | VF (V) | 3.1 | 3.1 | 2 |
| | Peak wavelength | 450 | 525 | 630 |
| | (nm) | | | |
| | Treatment on side | None | None | Ag plating |
| | surface | | | |
| Comparative | Luminosity (mcd) | 82 | 281 | 39 |
| Example 1 | VF (V) | 3.1 | 3.1 | 2 |
| | Peak wavelength | 450 | 525 | 630 |
| | (nm) | | | |
| | Treatment on side | None | None | None |
| | surface | | | |
| Effect | Rate of luminosity | 110% | 107% | 102% |
| | improvement | | | |

As shown in Table 1, it was confirmed that, in comparison to the LED lamps of Comparative Example 1 having no external reflection layer formed on the side surfaces of the red LED chips, the LED lamps of Example 1 exhibited improved luminosity with respect to all of the colors blue, green, and red. Particularly, it was confirmed that the rate of luminosity improvement was large in the blue and green LED chips which were adjacent to the red LED chips provided with the external reflection layer and had a shorter chip height than the red LED chips.

<Comparison Test 2>

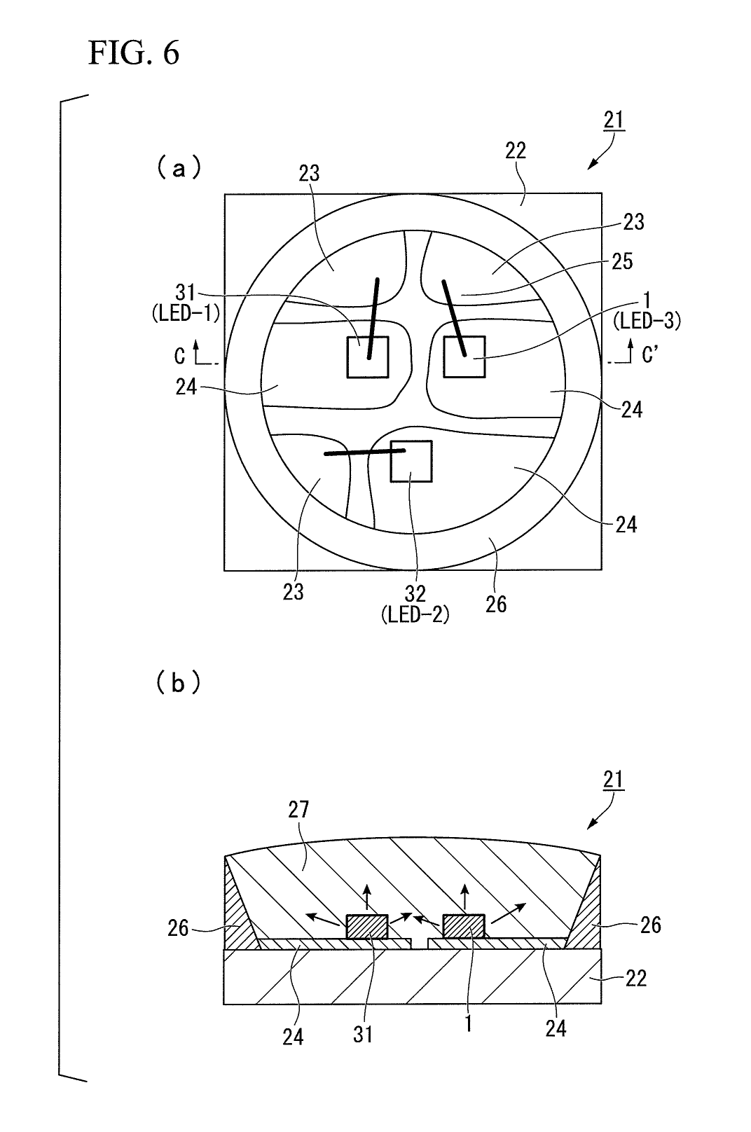

Differences between Comparison Test 2 and Comparison Test 1 are that the light emission wavelengths of LED chip light-emitting portions used for Example 2 and Comparative Example 2 were 612 nm, which is orange color, and that reflection films formed on LED chips used for Example 2 were made of gold (Au). In addition, LED lamps of Example 2 and Comparative Example 2 formed a package with 3 LED chips having the same light emission wavelength and the same chip height (see, FIG. 6). Meanwhile, other structures of the LED chips and the LED lamps were the same as the LED chips and the LED lamps used for Example 1 and Comparative Example 1 in Comparison Test 1.

(Manufacture of Light-Emitting Diode)

In the orange LED chips used for Example 2 and Comparative Example 2, a single crystal silicon substrate was used as the substrate, and ohmic electrodes were formed on the surfaces and the rear surface of the substrate, respectively. In addition, the thickness of the single crystal silicon substrate was set to 120 μm.

The substrate was cut into a 0.25 mm size using a dicing saw. After the surfaces of the light-emitting portion were protected, cutting-induced crushed layers were removed by etching; a 0.2 μm-thick Ni plating layer was formed on the side surfaces and the rear surface of the substrate; and a 0.3 μm-thick Au plating layer was formed, thereby forming an external reflection layer. Meanwhile, the Au reflection film had a reflectivity of 94% with respect to a wavelength of 612 nm.

In contrast to the above, in the orange LED chips used for Comparative Example 2, no external reflection layer was formed on the side surfaces and the rear surface of the substrate.

(Manufacture of Light-Emitting Diode Lamp)

Using three orange LED chips used for Example 2 and Comparative Example 2, which had been manufactured in the above manner, single color LED lamps (light-emitting diode lamps) as shown in FIGS. 6(a) and 6(b) were assembled (LED lamps of Example 2 and Comparative Example 2).

(Evaluation Results of Light Emission Characteristics)

With regard to the LED lamps of Example 2 and Comparative Example 2, three LEDs were made to emit light one by one, and the light emission characteristics of each LED chip were evaluated. Table 2 shows the evaluation results of the light emission characteristics.

TABLE 2

| | Item | LED-1 | LED-2 | LED-3 |
|---|---|---|---|---|
| | (IF = 20 mA) | Orange | Orange | Orange |
| Example 2 | Luminosity (mcd) | 150 | 151 | 153 |
| | VF (V) | 2 | 2 | 2 |
| | Peak wavelength | 612 | 612 | 612 |
| | (nm) | | | |
| | Treatment on side | Au plating | Au plating | Au plating |
| | surface | | | |
| Comparative | Luminosity (mcd) | 144 | 145 | 145 |
| Example 2 | VF (V) | 2 | 2 | 2 |
| | Peak wavelength | 612 | 612 | 612 |
| | (nm) | | | |
| | Treatment on side | None | None | None |
| | surface | | | |
| Effect | Rate of luminosity | 104% | 104% | 106% |
| | improvement | | | |

As shown in Table 2, when 20 mA of electric current was applied to each of the LED chips, in comparison to the LED lamps of Comparative Example 2 having no external reflection layer formed on the side surfaces of the orange LED chips, the LED lamps of Example 2 exhibited a 4% to 6% improved luminosity in all three mounted LED chips. That is, it was confirmed that, since Au is a material having a high reflectivity with respect to orange, absorption of light in the package was reduced so that the increase in luminosity could be achieved.

<Comparison Test 3>

Differences between Comparison Test 3 and Comparison Test 2 are that the light emission wavelengths of LED chip light-emitting portions used for Example 3 and Comparative Example 3 were 630 nm, which is red color, and that reflection films formed on LED chips used for Example 3 were made of copper (Cu). Meanwhile, other structures of the LED chips and the LED lamps were the same as the LED chips and the LED lamps used for Example 2 and Comparative Example 2 in Comparison Test 2.

(Manufacture of Light-Emitting Diode)

In the red LED chips used for Example 3, after a 0.2 μm-thick Ni plating layer was formed on the side surfaces and the rear surface of the substrate, a 0.5 μm-thick Cu plating layer was formed so as to form an external reflection layer. Meanwhile, the Cu reflection film had a reflectivity of 96% with respect to a wavelength of 630 nm.

In contrast to the above, in the red LED chips used for Comparative Example 3, no external reflection layer was formed on the side surfaces and the rear surface of the substrate.

(Manufacture of Light-Emitting Diode Lamp)

Using three red LED chips used for Example 3 and Comparative Example 3, which had been manufactured in the above manner, single color LED lamps (light-emitting diode lamps) as shown in FIGS. 6(a) and 6(b) were assembled (LED lamps of Example 3 and Comparative Example 3).

(Evaluation Results of Light Emission Characteristics)

With regard to the LED lamps of Example 3 and Comparative Example 3, three LEDs were made to emit light one by one, and the light emission characteristics of each LED chip were evaluated. Table 3 shows the evaluation results of the light emission characteristics.

TABLE 3

| | Item | LED-1 | LED-2 | LED-3 |
|---|---|---|---|---|
| | (IF = 20 mA) | Red | Red | Red |
| Example 3 | Luminosity (mcd) | 112 | 111 | 110 |
| | VF (V) | 2 | 2 | 2 |
| | Peak wavelength | 630 | 630 | 630 |
| | (nm) | | | |
| | Treatment on side | Cu plating | Cu plating | Cu plating |
| | surface | | | |
| Comparative | Luminosity (mcd) | 106 | 107 | 105 |
| Example 3 | VF (V) | 2 | 2 | 2 |
| | Peak wavelength | 630 | 630 | 630 |
| | (nm) | | | |
| | Treatment on side | None | None | None |
| | surface | | | |
| Effect | Rate of luminosity | 106% | 104% | 105% |
| | improvement | | | |

As shown in Table 3, when 20 mA of electric current was applied to each of the LED chips, in comparison to the LED lamps of Comparative Example 3 having no external reflection layer formed on the side surfaces of the LED chips, the LED lamps of Example 3 exhibited a 4% to 6% improved luminosity in all three mounted LED chips. That is, it was confirmed that, since Cu is a material having a high reflectivity with respect to red, absorption of light in the package was reduced so that the increase in luminosity could be achieved.

### INDUSTRIAL APPLICABILITY

The light-emitting diode of the invention is a light-emitting diode having an unprecedentedly high luminance and efficiency by reducing light absorption in a package, and can be used for a variety of display lamps, lighting devices, or the like.

### REFERENCE SIGNS LIST

1, 31, 32 . . . LIGHT-EMITTING DIODE
2 . . . COMPOUND SEMICONDUCTOR LAYER
3 . . . SUBSTRATE
4 . . . EXTERNAL REFLECTION LAYER
5 . . . METALLIC CONNECTION LAYER
6 . . . FIRST ELECTRODE
7 . . . SECOND ELECTRODE
8 . . . LIGHT-EMITTING PORTION
9 . . . LIGHT-EMITTING LAYER
10 . . . LOWER CLADDING LAYER
11 . . . UPPER CLADDING LAYER
12 . . . INTERNAL REFLECTION LAYER
12a . . . REFLECION FILM
12b . . . TRANSPARENT CONDUCTIVE FILM
13 . . . BARRIER LAYER
14 . . . CONNECTION LAYER
14a . . . LOW MELTING POINT METAL LAYER
14b . . . Au LAYER
15 . . . SEMICONDUCTOR SUBSTRATE
16 . . . BUFFER LAYER
17 . . . CONTACT LAYER
18 . . . p-TYPE GaP LAYER
21 . . . LIGHT-EMITTING DIODE LAMP
22 . . . MOUNTING SUBSTRATE
23 . . . n ELECTRODE TERMINAL
24 . . . p ELECTRODE TERMINAL
25 . . . GOLD WIRE
26 . . . REFLECTION WALL
27 . . . SEALING MATERIAL

1. A light-emitting diode, comprising a compound semiconductor layer which includes a light-emitting portion having a light-emitting layer and a substrate,
wherein an external reflection layer having a reflectivity higher than that of the substrate is provided on a side surface of the substrate.

2. The light-emitting diode according to claim 1,
wherein the compound semiconductor layer and the substrate are joined; and
the substrate is any of Si, Ge, a metal, a ceramic, and GaP.

3. The light-emitting diode according to claim 1,
wherein the external reflection layer has a reflectivity of 90% or higher in the wavelength band of external light.

4. The light-emitting diode according to claim 1,
wherein the external reflection layer is constituted by a metal including at least one of silver, gold, copper, and aluminum.

5. The light-emitting diode according to claim 1,
wherein a stabilization layer is provided on the surface of the external reflection layer.

6. The light-emitting diode according to claim 1,
wherein an internal reflection layer is provided between the compound semiconductor layer and the substrate.

7. The light-emitting diode according to claim 1,
wherein the external reflection layer is formed by a plating method.

8. The light-emitting diode according to claim 1,
wherein the light-emitting layer includes an AlGaInP or AlGaAs layer.

9. A method for manufacturing a light-emitting diode, comprising:
a process in which a compound semiconductor layer including a light-emitting portion having a light-emitting layer is formed on a semiconductor substrate;
a process in which the compound semiconductor layer and the substrate are joined;
a process in which the semiconductor substrate is removed; and
a process in which an external reflection layer is formed on a side surface of the substrate.

10. The method for manufacturing a light-emitting diode according to claim 9,
wherein the process in which an external reflection layer is formed on a side surface of the substrate includes a plating process.

11. A light-emitting diode lamp in which two or more light-emitting diodes are mounted,
wherein at least one light-emitting diode according to claim 1 is mounted.

12. The light-emitting diode lamp according to claim 11,
wherein light emission wavelengths of the mounted light-emitting diodes are different.

13. The light-emitting diode lamp according to claim 11,
wherein the chip heights of the mounted light-emitting diodes are different.
